(19) United States
(12) Patent Application Publication
(10) Pub. No.: US 2024/0194450 A1
(43) Pub. Date: Jun. 13, 2024

(54) PLASMA PROCESSING DEVICE AND PLASMA PROCESSING METHOD

(71) Applicant: Hitachi High-Tech Corporation, Minato-ku, Tokyo (JP)

(72) Inventors: Yasushi Sonoda, Tokyo (JP); Motohiro Tanaka, Tokyo (JP); Yusuke Nakatani, Tokyo (JP)

(21) Appl. No.: 17/907,857

(22) PCT Filed: Jun. 28, 2021
(86) PCT No.: PCT/JP2021/024374

§ 371 Date: Aug. 29, 2022

(51) Int. Cl. H01J 37/32; H01L 21/67

(52) U.S. Cl. CPC H01J 37/32201; H01J 2237/327; H01L 21/67069

(57) ABSTRACT

A plasma processing device and method which allow control of a density ratio between ions and radicals, including a processing chamber, a radio frequency power supply which supplies microwave radio frequency power for plasma generation, a magnetic field generating mechanism which generates a magnetic field in the processing chamber, a sample stand disposed in the processing chamber, and a shielding plate disposed above the sample stand for shielding incidence of an ions onto the sample stand. The magnetic field generating mechanism includes a coil disposed around an outer periphery of the processing chamber, and a power supply connected to the coil. The mechanism allows a power supply of the magnetic field generating mechanism or the radio frequency power supply to control a plasma generating position with respect to the shielding plate, and to generate plasma by periodically changing the plasma generating position vertically with respect to the shielding plate.

### TECHNICAL FIELD

The present invention relates to a plasma processing device and a plasma processing method. Specifically, the present invention relates to a technique effectively applicable to the plasma processing device and the plasma processing method for performing plasma processing operations onto the surface of the semiconductor substrate or the like by executing both anisotropic etching process through supply of ions and radicals, and isotropic etching process through supply of only radicals.

### BACKGROUND ART

The structure of the semiconductor device has been increasingly complicated and highly integrated to satisfy market demands such as power saving and acceleration. Application of a GAA (Gate All Around) structure which constitutes the channel using laminated nanowires to the logic device has been under consideration. The etching process step for forming the GAA structure requires execution of the vertical processing (vertical etching) through the anisotropic etching, and a lateral etching through the isotropic etching. Based on the feature that the ion has its energy vertically biased to the surface of the semiconductor substrate (wafer), the anisotropic etching is executed using ion assisting reaction in which the radical reaction is facilitated by the energy only in the vertical direction. Meanwhile, when execution of etching parallel (lateral) to the wafer surface is required, the isotropic etching with no anisotropy is executed mainly utilizing the surface reaction with only radicals. Since the ion serves to facilitate the etching in the vertical direction, it is preferable to remove the ion from plasma (that is, from particle species supplied to the wafer) upon execution of the isotropic etching. The plasma processing device for executing the etching process to form the GAA structure requires the use of the device capable of executing the anisotropic etching through supply of ions and radicals to the wafer, and the device capable of executing the isotropic etching through supply of only radicals.

Conventionally, the plasma processing device for vertical processing through supply of ions and radicals, and the plasma processing device for executing the isotropic processing through supply of only radicals have been often employed as different devices. If the single device is configured to have both processing operations executable, the installation area of the device, and the number of the installed devices can be reduced, leading to reduction in the device cost. Concerning the foregoing requirement, PTL 1 (Japanese Patent Application Laid-Open No. 2018-093226) discloses the plasma processing device which includes a processing chamber in which the sample is plasma processed, a radio frequency power supply which supplies microwave radio frequency power for generating plasma in the processing chamber, a magnetic field generating mechanism for generating the magnetic field in the processing chamber, and a sample stand on which the sample is placed. The device further includes a shielding plate disposed above the sample stand for shielding incidence of ion onto the sample stand, and a control unit for selectively executing a control operation for generating plasma above the shielding plate, and another control operation for generating plasma below the shielding plate. The former control operation for generating plasma above the shielding plate controls the magnetic field generating mechanism so that the magnetic flux density position is above the shielding plate for electron cyclotron resonance with the microwave. The latter control operation for generating plasma below the shielding plate controls the magnetic field generating mechanism so that the magnetic flux density position is below the shielding plate. There are provided the plasma processing device which allows the single device to execute a radical irradiation step and an ion irradiation step and to control the ion irradiation energy in the range from several tens eV to several KeV, and the plasma processing method using the plasma processing device.

The anisotropic etching to be executed through supply of radicals and ions requires highly accurate etching technique. Since the etching process is executed through chemical reaction between the wafer surface and the radical, it is essential to control density of the radical to be supplied to the wafer for attaining the highly accurate plasma etching. As one of techniques of controlling the radical density, the plasma etching method using pulse discharging has been known. In the method as disclosed in PTL 2 (Japanese Unexamined Patent Application Publication No. Hei 09-185999), the density and the composition of the radical is controlled by measuring the density and the composition of the radical generated by reactive gas decomposition in plasma, and pulse modulating power of the plasma generator in a prescribed period for controlling the pulse modulation duty ratio based on the measurement result.

### CITATION LIST

### Patent Literature

PTL 1: Japanese Unexamined Patent Application Publication No. 2018-093226

PTL 2: Japanese Unexamined Patent Application Publication No. Hei 09-185999

### SUMMARY OF INVENTION

### Technical Problem

The single unit of the device has been demanded to attain two tasks, that is, execution of the anisotropic etching process through supply of ions and radicals and isotropic etching process through supply of only radicals, and execution of highly accurate anisotropic etching process through supply of ions and radicals for microstructure processing.

The etching process using pulse discharging as disclosed in PTL 2 requires measurement of the relationship between the pulse modulation duty ratio and the radical density. Accordingly, the relationship between the duty ratio and the radical density cannot be easily clarified.

It is an object of the present invention to provide the technique relating to the plasma processing device and the plasma processing method for attaining direct control of the density ratio between ion and radical in the anisotropic etching process through supply of ions and radicals.

### Solution to Problem

The present invention provides a plasma processing device which includes a processing chamber in which a sample is plasma processed, a radio frequency power supply which supplies microwave radio frequency power for plasma generation in the processing chamber, a magnetic field generating mechanism for generating the magnetic field in the processing chamber, a sample stand disposed in the processing chamber, on which the sample is placed, and a shielding plate disposed above the sample stand for shielding incidence of ion onto the sample stand. The magnetic field generating mechanism includes a coil disposed around an outer periphery of the processing chamber, and a power supply connected to the coil. The mechanism allows the power supply of the magnetic field generating mechanism or the radio frequency power supply to control a plasma generation position with respect to the shielding plate, and generate plasma by periodically changing the plasma generation position vertically with respect to the shielding plate.

### Advantageous Effects of Invention

The present invention provides the technique relating to the plasma processing device and the plasma processing method, which allow direct control of the density ratio between ion and radical in the anisotropic etching process through supply of ions and radicals.

### BRIEF DESCRIPTION OF DRAWINGS

FIG. 1 is a vertical sectional view schematically illustrating a plasma etching device according to Example 1 of the present invention.

FIG. 2A illustrates currents for setting an ECR region centered by DC coil current power supplies according to Example 1 of the present invention.

FIG. 2B illustrates currents for setting the ECR region centered by the DC coil current power supplies according to Example 1 of the present invention.

FIG. 3A illustrates currents of an AC coil current power supply for vertically moving the ECR region illustrated in FIG. 2A as an initially set position with respect to an ion shielding plate.

FIG. 3B illustrates currents of the AC coil current power supply for vertically moving the ECR region illustrated in FIG. 2B as an initially set position with respect to the ion shielding plate.

FIG. 4 is a vertical sectional view schematically illustrating a plasma etching device according to Example 2 of the present invention.

FIG. 5A illustrates currents for setting the ECR region corresponding to a center frequency of a variable frequency electromagnetic wave generating power supply by the DC coil current power supplies according to Example 2 of the present invention.

FIG. 5B illustrates currents for setting the ECR region corresponding to the center frequency of the variable frequency electromagnetic wave generating power supply by the DC coil current power supplies according to Example 2 of the present invention.

FIG. 6A illustrates currents of the AC coil current power supply for vertically moving the ECR region with respect to the ion shielding plate by changing the frequency of the variable frequency electromagnetic wave generating power supply while centering the ECR region corresponding to the center frequency as illustrated in FIG. 5A.

FIG. 6B illustrates currents of the AC coil current power supply for vertically moving the ECR region with respect to the ion shielding plate by changing the frequency of the variable frequency electromagnetic wave generating power supply while centering the ECR region corresponding to the center frequency as illustrated in FIG. 5B.

### DESCRIPTION OF EMBODIMENT

Embodiments of the present invention will be described referring to the drawings.

### Example 1

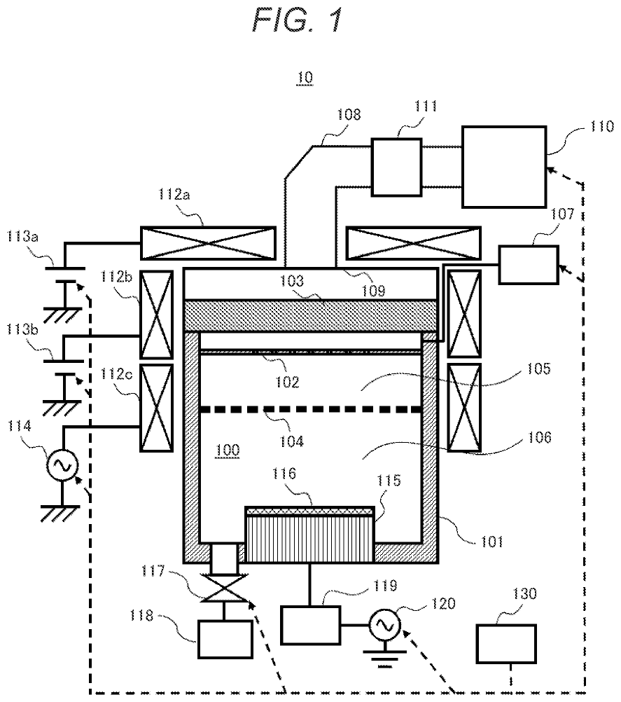

FIG. 1 is a vertical sectional view schematically illustrating an overall structure of a plasma processing device according to this example. A plasma processing device 10 as illustrated in FIG. 1 includes a processing chamber 100 formed in a vacuum vessel 101. The processing chamber 100 is constituted by providing a shower plate 102 and a dielectric window 103 in an upper section of the vacuum vessel 101. The shower plate 102 serves to introduce etching gas into the processing chamber 100 in the vacuum vessel 101, and the dielectric window 103 air-tightly seals the upper section of the processing chamber 100.

A gas supply device 107 is connected to an area between the shower plate 102 and the dielectric window 103 via a gas piping so that gas such as oxygen and chlorine is supplied for executing the plasma etching process. A vacuum exhaust device 118 is connected to the vacuum vessel 101 via a pressure control valve 117 so that the pressure of the processing chamber 100 is controlled.

A waveguide 108 (or antenna) for irradiation of an electromagnetic wave is disposed above the dielectric window 103 so that plasma generating power is transmitted to the processing chamber 100. An oscillated electromagnetic wave is transmitted from an electromagnetic wave generating power supply (radio frequency power supply) 110 to the waveguide 108 (or antenna) via an electromagnetic wave matching unit 111. In Example 1, the frequency of radio frequency current output from the electromagnetic wave generating power supply 110 is kept constant. A cavity resonator 109 is disposed to allow the electromagnetic wave transmitted from the waveguide 108 to generate a standing wave in a specific mode in the processing chamber 100. In this example, the frequency of microwave as the electromagnetic wave is set to 2.45 GHz, which is not specifically limited. Magnetic field generating coils 112 (112a, 112b, and 112c) are disposed around an outer periphery of the processing chamber 100. For current controlling operations, the magnetic field generating coils 112a and 112b are connected to DC coil current power supplies 113 (113a and 113b), respectively, and the magnetic field generating coil 112c is connected to an AC coil current power supply 114. The magnetic field generating coils 112a and 112b are driven by the DC current output from the DC coil current power supplies 113. The magnetic field generating coil 112c is driven by the AC current output from the AC coil current power supply 114. The magnetic field generating coils 112, the DC coil current power supplies 113, and the AC coil current power supply 114 may be regarded as components of a magnetic field generating mechanism. Specifically, the magnetic field generating coils 112a and 112b may be called first coils, and the magnetic field generating coil 112c may be called a second coil.

Plasma is generated in the processing chamber 100 by power oscillated by the electromagnetic wave generating power supply 110 through electron cyclotron resonance (ECR: Electron Cyclotron Resonance) with the magnetic field generated by the magnetic field generating coil 112.

An electrode substrate 115 serving as a mount stand (sample stand) of a semiconductor processing substrate (semiconductor substrate) 116 as the sample is disposed on the lower section of the processing chamber 100 opposing to the shower plate 102. A radio frequency power supply 120 is connected to the electrode substrate 115 via a radio frequency matching unit 119. A negative voltage generally called self-bias is generated on the electrode substrate 115 through supply of radio frequency power from the radio frequency power supply 120 connected to the electrode substrate 115. The self-bias causes acceleration of ions in plasma, and vertical incidence of the ions onto the semiconductor processing substrate 116 which is then subjected to the etching process.

The processing chamber 100 includes an ion shielding plate 104 between the shower plate 102 and the semiconductor processing substrate 116. The ion shielding plate 104 divides the inner space of the processing chamber 100 into upper and lower regions. In the specification, the upper region above the ion shielding plate 104 will be called a first region or a radical region 105, and the lower region below the ion shielding plate 104 will be called a second region or a RIE (Reactive Ion Etching) region 106. The magnetic field generating coils 112a and 112b are disposed at the side above the ion shielding plate 104. The magnetic field generating coil 112c is disposed below the magnetic field generating coils 112a and 112b, and placed close to the ion shielding plate 104.

Generation of plasma through ECR with an electromagnetic wave at 2.45 GHz requires the magnetic field with magnetic flux density of 0.0875 T (tesla). The region where the magnetic flux density in the processing chamber 100 is 0.0875 T will be defined as the position of the ECR region. In order to generate the strong magnetic field, the magnetic field generating coil 112 with self-inductance ranging from 100 to 1000 mH is used to allow the DC coil current power supplies 113 and the AC coil current power supply 114 to supply current ranging from approximately 10 to 60 A. The position of the ECR region in the processing chamber 100 is accurately controlled by controlling each value of currents supplied from multiple DC coil current power supplies 113 and the AC coil current power supply 114 to the magnetic field generating coils 112 connected to the respective power supplies. This allows movement of the plasma generating position with respect to the semiconductor processing substrate 116. The magnetic field generating coils 112a and 112b are positioned at the side above the ion shielding plate 104. The magnetic field generated by the coils 112a and 112b in the radical region 105 located therearound is made stronger than the magnetic field in the RIE region 106 for the following reason. That is, weakening in the magnetic field toward the ECR region from the incidence direction of the electromagnetic wave is effective for satisfying the requirement of propagating the electromagnetic wave to the ECR region where plasma is generated. In other words, the magnetic field is made stronger in the direction toward the waveguide 108 seen from the ECR region, or toward the radical region 105 seen from the RIE region 106.

As described above, the ion shielding plate 104 is disposed between the shower plate 102 and the mount stand of the semiconductor processing substrate 116 in the processing chamber 100 so that its space is divided into two regions, that is, the radical region 105 above the ion shielding plate 104 and the reactive ion etching (RIE: Reactive Ion Etching) region 106 below the shielding plate 104.

If plasma is generated by positioning the ECR region in the radical region 105, the ion shielding plate 104 between the semiconductor processing substrate 116 and the plasma prevents ions therein from reaching the semiconductor processing substrate 116 but allows supply of only radicals to the semiconductor processing substrate 116 because of the effect of the ion shielding plate 104. The semiconductor processing substrate 116 is then plasma processed through radical etching (isotropic etching).

If plasma is generated by positioning the ECR region in the RIE region 106, both ions and radicals are supplied to the semiconductor processing substrate 116 from plasma because there is no shielding between the plasma and the semiconductor processing substrate 116. The semiconductor processing substrate 116 is then plasma processed through the RIE (anisotropic etching).

A control unit 130 is connected to the gas supply device 107, the pressure control valve 117, the electromagnetic wave generating power supply 110, the DC coil current power supplies 113, the AC coil current power supply 114, and the radio frequency power supply 120 so that the plasma processing device 10 is controlled in accordance with the processing condition. Assuming that the process condition includes multiple plasma processing steps, the control unit 130 controls the respective device parameters sequentially in accordance with the corresponding processing steps to execute the etching process to the semiconductor processing substrate 116.

If the ECR region is positioned above the ion shielding plate 104, the radical is only supplied to the semiconductor processing substrate 116. If the ECR region is positioned below the ion shielding plate 104, the radical and the ion are supplied to the semiconductor processing substrate 116. Accordingly, the ECR region is periodically positioned between two regions so that the reactive ion etching is executed by controlling the density ratio between ion and radical. In the normal RIE, the plasma generating time is entirely spent only in the RIE region 106. Meanwhile, plasma is generated in the radical region 105 in addition to the RIE region 106 so that the time period for which the radical is only supplied can be secured in addition to the time period for which the ion and the radical are supplied. Selection of the plasma generating region periodically between the RIE region 106 and the radical region 105 lowers the ion density as a whole, resulting in the RIE with increased radical density ratio. Since the ion is supplied only in the time period for which plasma is generated in the RIE region 106, the ion content to be supplied to the semiconductor processing substrate 116 is proportional to the rate of the time period selected for positioning in the RIE region 106 to the cycle time for periodically selecting the position of the ECR region in a cycle. Increase in the time period for which the ECR region is positioned in the RIE region 106 raises the ion content ratio, and increase in the time period for which the ECR region is positioned in the radical region 105 raises the radical amount ratio. The density ratio between ion and radical can be changed in accordance with the ratio between the time period for which the ECR region is positioned in the RIE region 106 and the time period for which the ECR region is positioned in the radical region 105 in a cycle.

The periodical positional control of the ECR region, and change in the ratio of time period for positioning the ECR region between the radical region 105 and the RIE region 106 are performed in the following manner. That is, the center position of the ECR region is set by the DC current output from the DC coil current power supplies (DC power supplies) 113, and the position of the ECR region is vertically moved by the AC current output from the AC coil current power supply (AC power supply) 114.

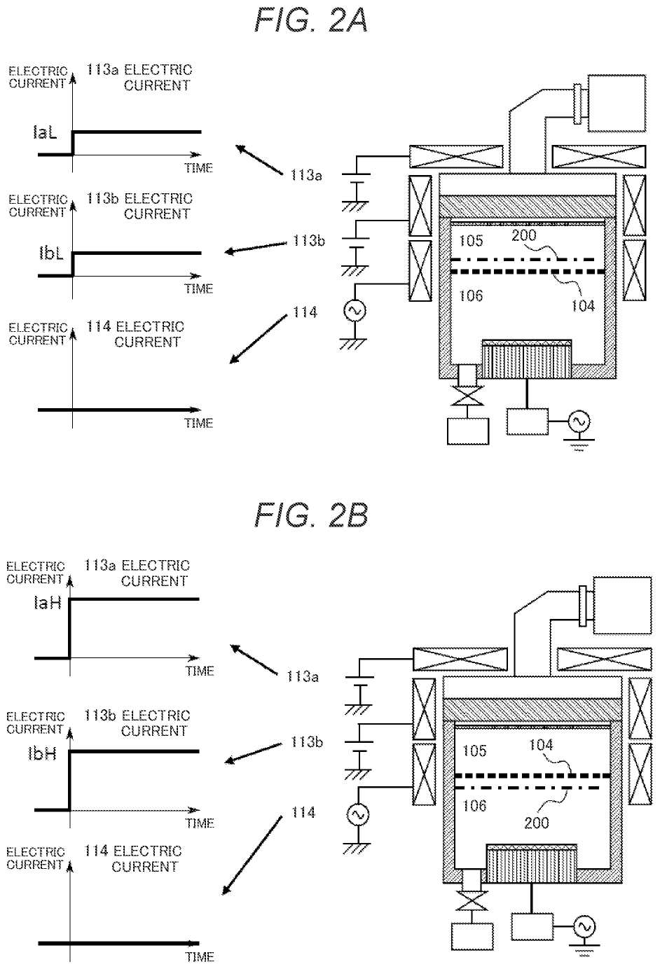

FIGS. 2A and 2B illustrate examples in which the ECR region is positioned by the DC coil current power supplies 113. The position of the ECR region may be regarded as the center position of the ECR region. The magnetic field generated by the magnetic field generating coils 112a and 112b is weakened from the radical region 105 toward the RIE region 106, and the magnetic field stronger than that of the ECR region is generated in the upper section of the vacuum vessel 101 (or processing chamber 100). Accordingly, as the current becomes higher, the ECR region moves downward in the vacuum vessel 101 (or processing chamber 100). As FIG. 2A illustrates, in the case of lower currents (IaL, IbL) of the DC coil current power supplies 113a and 113b, a position 200 of the resultant ECR region is located in the radical region 105 above the ion shielding plate 104. Meanwhile, as FIG. 2B illustrates, in the case of higher currents (IaH>IaL, IbH>IbL) from the DC coil current power supplies 113a and 113b, the position 200 of the resultant ECR region is located in the RIE region 106 below the ion shielding plate 104.

Referring to the plasma processing device 10 as illustrated in FIG. 1, among two kinds of coil current power supplies, that is, the DC coil current power supplies 113 and the AC coil current power supply 114, only the magnetic field generating coil 112c which is the closest to the ion shielding plate 104 is connected to the AC coil current power supply 114. The magnetic field generating coils 112a and 112b farther distant from the ion shielding plate 104 than the magnetic field generating coil 112c are connected to the DC coil current power supplies 113, respectively. Since the magnetic field generated by the coil is made strong as it becomes closer to the coil, the current of the closest magnetic field generating coil 112c is more effective for the strength of the magnetic field around the ion shielding plate 104. When vertical movement of the ECR region is required with respect to the ion shielding plate 104, the magnetic field strength around the ion shielding plate 104 has to be changed. The requirement may be satisfied by changing the current of the closest magnetic field generating coil 112c.

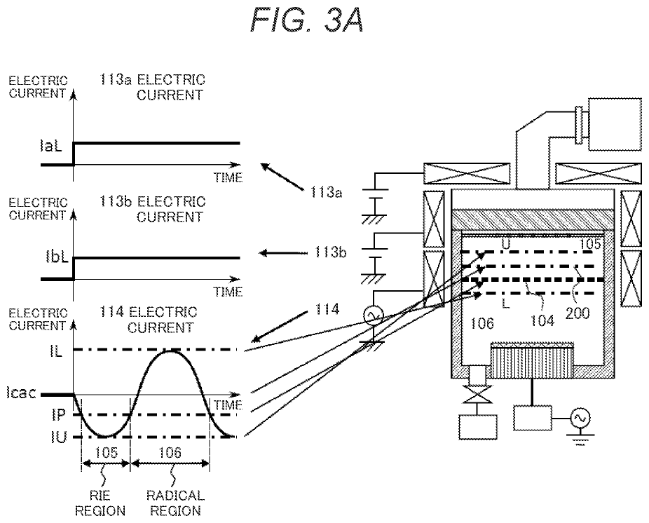

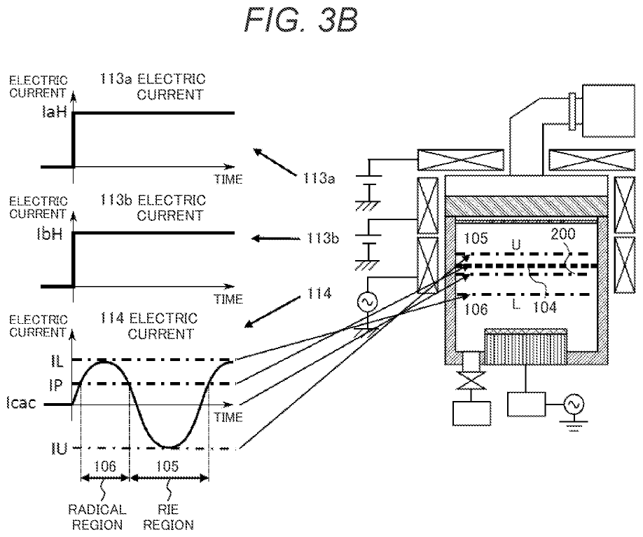

FIGS. 3A and 3B illustrate examples each indicating that the ECR region has been vertically moved by AC current of the magnetic field generating coil 112c from the position 200 of the ECR region initially set by the magnetic field generation coils 112a and 112b. Each of the examples illustrates an upper limit U and a lower limit L of the position 200 of the ECR region, the position of the ion shielding plate 104, and current values (IU, IL, IP) corresponding to those positions, respectively. In the case of a positive value of an AC Icac carried through the magnetic field generating coil 112c by the AC coil current power supply 114, the position of the ECR region moves downward in the vacuum vessel 101 (or processing chamber 100). In the case of a negative value of the AC Icac, the position of the ECR region moves upward in the vacuum vessel 101 (or processing chamber 100). If the position 200 of the ECR region has been initially set in the radical region 105 by the DC coil current power supplies 113 as illustrated in FIG. 3A, the time period for which the ECR region is positioned in the radical region 105 becomes longer than the time period for which the ECR region is positioned in the RIE region 106. If the position 200 of the ECR region has been initially set in the RIE region 106 by the DC current power supplies 113 as illustrated in FIG. 3B, the time period for which the ECR region is positioned in the RIE region 106 becomes longer than the time period for which the ECR region is positioned in the radical region 105. The current Icac carried through the magnetic field generating coil 112c moves the position of the ECR region between the radical region 105 and the RIE region 106 periodically. In other words, the control unit 130 controls the DC coil current power supplies 113 and the AC coil current power supply 114 to periodically change the position 200 of the electron cyclotron resonance (ECR) region which has been caused by interaction between the microwave and the magnetic field. In a single cycle, the position 200 of the electron cyclotron resonance (ECR) region moves downward from the position above the shielding plate 104 to the position below the shielding plate 104, or upward from the position below the shielding plate 104 to the position above the shielding plate 104.

An explanation will be made with respect to a plasma processing method using the plasma processing device 10.

Step 1 A process step is executed for mounting the semiconductor substrate 116 as the sample on the mount stand 115 in the processing chamber 100 so that the GAA structure is formed on a surface of the semiconductor substrate.

Step 2 A process step is executed for controlling a pressure in the processing chamber 100 by operating the pressure control valve 117 and the vacuum exhaust device 118.

Step 3 A process step is executed for supplying etching gas such as oxygen and chlorine to an area between the shower plate 102 and the dielectric window 103 of the processing chamber 100 from the gas supply device 107 so as to apply plasma etching process.

Step 4 A process step is executed for generating plasma in the processing chamber 100 by operating the electromagnetic wave generating power supply 110, the DC coil current power supplies 113, and the AC coil current power supply 114 so that the surface of the semiconductor substrate 116 is plasma processed through plasma etching.

The step 4 may bring about any one of a first state, a second state, and a third state as described below.

As FIG. 2A illustrates, in the first state, the ECR region is positioned above the ion shielding plate 104 for executing the isotropic etching operation.

As FIG. 2B illustrates, in the second state, the ECR region is positioned below the ion shielding plate 104 for executing the anisotropic etching operation.

As FIG. 3A or 3B illustrates, in the third state, the position of the ECR region is vertically moved periodically with respect to the ion shielding plate 104 for executing the highly accurate anisotropic etching operation by controlling the density ratio between ion and radical.

Example 1 provides one or more advantageous effects as described below.
1) The single unit of the plasma processing device 10 can be configured to attain execution of the anisotropic etching process through supply of ions and radicals, and the isotropic etching process through supply of only radicals.
2) The technique allows direct control of the density ratio between ion and radical upon execution of the anisotropic etching process through supply of ions and radicals.
3) The highly accurate plasma etching technique can be implemented by controlling density of the radical to be supplied to the surface of the semiconductor processing substrate (wafer) with high accuracy upon execution of the anisotropic etching process through supply of radicals and ions.

In this example, three magnetic field generating coils 112 (112a, 112b, and 112c) are used. However, the number of the coils to be used is not limited. Multiple magnetic field generating coils are connected to the AC coil current power supply in a closest-first order from the ion shielding plate 104 successively. The DC coil current power supply can be connected to the remaining magnetic field generating coil.

If the magnetic field in the plasma processing chamber is changed using the radio frequency power supply, the radio frequency induced current flows in plasma. This may cause the risk of generating the inductive coupling plasma in the condition where such induced current generates plasma continuously. The generated plasma which is different from the plasma generated through the ECR prevents control of the plasma generation position under the control of the ECR region position. It is preferable to set the frequency of the AC coil current power supply to 1 kHz or lower so as not to generate the inductive coupling plasma.

As FIGS. 3A and 3B illustrate, the AC coil current power supply 114 outputs the sine wave. However, it is not limited to the sine wave. Arbitrary AC power supply can be used so long as the periodically variable waveform such as a square wave is output besides the sine wave.

### Example 2

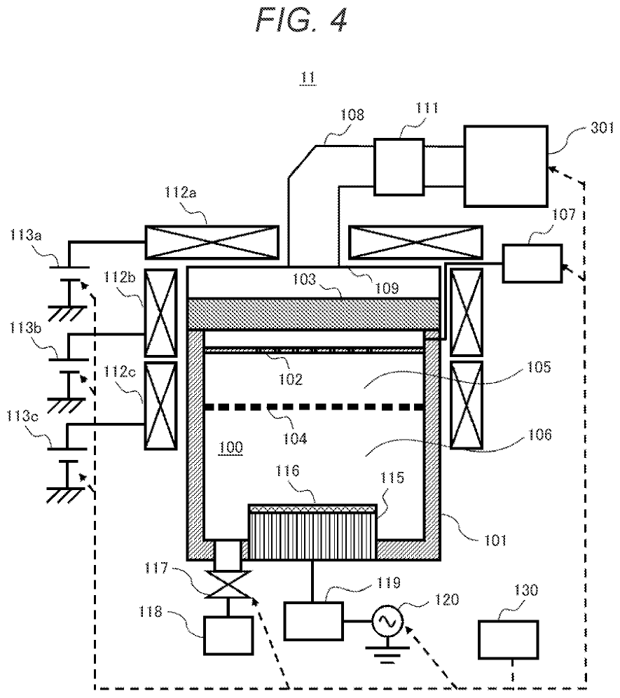

FIG. 4 is a vertical sectional view schematically illustrating an overall structure of a plasma processing device according to this example. A plasma processing device 11 includes the processing chamber 100 formed in the vacuum vessel 101. The processing chamber 100 is constituted by providing the shower plate 102 and the dielectric window 103 in the upper section of the vacuum vessel 101. The shower plate 102 serves to introduce etching gas into the vacuum vessel 101, and the dielectric window 103 air-tightly seals the upper section of the processing chamber 100.

The gas supply device 107 is connected to the shower plate 102 via the gas piping so that gas such as oxygen and chlorine is supplied for executing the plasma etching process. The vacuum exhaust device 118 is connected to the vacuum vessel 101 via the pressure control valve 117 so that the pressure of the processing chamber 100 is controlled. The ion shielding plate 104 is provided in the processing chamber 100 similar to Example 1.

The waveguide 108 (or antenna) for irradiation of an electromagnetic wave is disposed above the dielectric window 103 so that plasma generating power is transmitted to the processing chamber 100. An oscillated electromagnetic wave is transmitted from a variable frequency electromagnetic wave generating power supply (variable frequency radio frequency power supply) 301 to the waveguide 108 via the electromagnetic wave matching unit 111. The cavity resonator 109 is disposed to allow the electromagnetic wave transmitted from the waveguide 108 to generate a standing wave in a specific mode in the processing chamber 100. In this example, the frequency of microwave as the electromagnetic wave is set to be in a range from 1.80 GHz to 2.45 GHz of microwave although it is not specifically limited. The magnetic field generating coils 112 (112a, 112b, and 112c) are disposed around the outer periphery of the processing chamber 100. The magnetic field generating coils 112a, 112b, and 112c are connected to the DC coil current power supplies 113 (113a, 113b, and 113c), respectively for current controlling operations. The magnetic field generating coils 112 and the DC coil current power supplies 113 may be regarded as components of a magnetic field generating mechanism. Power oscillated by the variable frequency electromagnetic wave generating power supply 301 generates plasma in the processing chamber 100 through the electron cyclotron resonance (ECR: Electron Cyclotron Resonance) with the magnetic field generated by the magnetic field generating coils 112.

The electrode substrate 115 serving as the mount stand (sample stand) of the semiconductor processing substrate 116 is disposed on the lower section of the processing chamber 100 opposing to the shower plate 102. The radio frequency power supply 120 is connected to the electrode substrate 115 via the radio frequency matching unit 119. The negative voltage generally called self-bias is generated on the electrode substrate 115 through supply of radio frequency power from the radio frequency power supply 120 connected to the electrode substrate 115. The self-bias causes acceleration of ions in plasma, and vertical incidence of the ions onto the semiconductor processing substrate 116 which is then subjected to the etching process.

The processing chamber 100 includes the ion shielding plate 104 between the shower plate 102 and the semiconductor processing substrate 116. The ion shielding plate 104 divides the inner space of the processing chamber 100 into upper and lower regions. In the specification, the upper region above the ion shielding plate 104 will be called the first region or the radical region 105, and the lower region below the ion shielding plate 104 will be called the second region or the RIE (Reactive Ion Etching) region 106.

Generation of plasma through ECR with an electromagnetic wave in the range from 1.80 GHz to 2.45 GHz requires the magnetic field with magnetic flux density in the range from 0.0643 T to 0.0875 T. The ECR region is defined as the region having the magnetic field strength which causes resonance corresponding to each of the respective frequencies in the processing chamber 100. In order to generate the strong magnetic field, the magnetic field generating coil 112 with self-inductance ranging from 100 to 1000 mH is used, and the DC coil current power supplies 113 (113a, 113b, and 113c) are configured to supply current ranging from approximately 10 to 60 A. The position of the ECR region in the processing chamber 100 is accurately controlled by controlling each value of currents supplied to the magnetic field generating coils 112 connected to multiple DC coil current power supplies 113, respectively. This allows movement of the plasma generating position with respect to the semiconductor processing substrate 116. The magnetic field generating coils 112a and 112b are positioned at the side above the ion shielding plate 104. The magnetic field generated by the coils 112a and 112b in the radical region 105 located therearound is made stronger than the magnetic field in the RIE region 106 for the following reason. That is, weakening in the magnetic field toward the ECR region from the incidence direction of the electromagnetic wave is effective for satisfying the requirement of propagating the electromagnetic wave to the ECR region where plasma is generated. In other words, the magnetic field is made stronger in the direction toward the waveguide 108 seen from the ECR region, or toward the radical region 105 seen from the RIE region 106.

As described above, the ion shielding plate 104 is disposed between the shower plate 102 and the semiconductor processing substrate 116 in the processing chamber 100 so that its space is divided into two regions, that is, the radical region 105 above the ion shielding plate 104 and the reactive ion etching (RIE: Reactive Ion Etching) region 106 below the shielding plate 104. If plasma is generated by setting the position 200 of the ECR region in the radical region 105, the ion shielding plate 104 between the semiconductor processing substrate 116 and the plasma prevents ions therein from reaching the semiconductor processing substrate 116, but allows supply of only radicals to the semiconductor processing substrate 116. The semiconductor processing substrate 116 is then plasma processed through the radical etching. If plasma is generated by setting the position 200 of the ECR region in the RIE region 106, ions and radicals are supplied to the semiconductor processing substrate 116 from plasma because there is no shielding between the plasma and the semiconductor processing substrate 116. The semiconductor processing substrate 116 is then plasma processed through the RIE.

The control unit 130 is connected to the gas supply device 107, the pressure control valve 117, the variable frequency electromagnetic wave generating power supply 301, the DC coil current power supplies 113, and the radio frequency power supply 120 so that the plasma processing device is controlled in accordance with the processing condition. Assuming that the processing condition includes multiple plasma processing steps, the control unit 130 controls the respective device parameters sequentially in accordance with the corresponding processing steps to execute the etching process to the semiconductor processing substrate 116.

In the present invention, if the ECR region is positioned above the ion shielding plate 104, the radical is only supplied to the semiconductor processing substrate 116. If the ECR region is positioned below the ion shielding plate 104, the radical and the ion are supplied to the semiconductor processing substrate 116. Accordingly, the ECR region is periodically positioned between two regions (105, 106) in a cycle so that the reactive ion etching is executed under the control of the density ratio between ion and radical. In the normal RIE, the plasma generating time is entirely spent only in the RIE region 106. Meanwhile, plasma is generated in the radical region 105 in addition to the RIE region 106 so that the time period for which the radical is only supplied to the semiconductor processing substrate 116 can be secured in addition to the time period for which the ion and the radical are supplied to the semiconductor processing substrate 116. Selection of the plasma generating region periodically between the RIE region 106 and the radical region 105 lowers the ion density as a whole, and allows execution of the RIE with increased radical density ratio. Since the ion is supplied to the semiconductor processing substrate 116 only in the time period for which plasma is generated in the RIE region 106, the ion content to be supplied to the semiconductor processing substrate 116 is proportional to the rate of the time period selected for positioning the ECR region in the RIE region 106 to the cycle time for periodically selecting the position of the ECR region in a cycle. Increase in the time period for positioning the ECR region in the RIE region 106 raises the ion content ratio, and increase in the time for positioning the ECR region in the radical region 105 raises the radical amount ratio. The density ratio between ion and radical can be changed in accordance with the ratio between the time period for positioning the ECR region in the RIE region 106 and the time period for positioning the ECR region in the radical region in a cycle.

The periodical positional control of the ECR region, and change in the ratio of time period set for positioning the ECR region between the radical region 105 and the RIE region 106 are performed in the following manner. Assuming that the frequency at the center of the frequency range of the variable frequency electromagnetic wave generating power supply 301 is in the range from 1.80 GHz to 2.45 GHz, the position of the ECR region corresponding to the center frequency of 2.13 GHz is set by the current output from the DC coil current power supplies 113. The position of the ECR region is vertically moved by changing the output frequency of the variable frequency electromagnetic wave generating power supply 301 corresponding to the magnetic field.

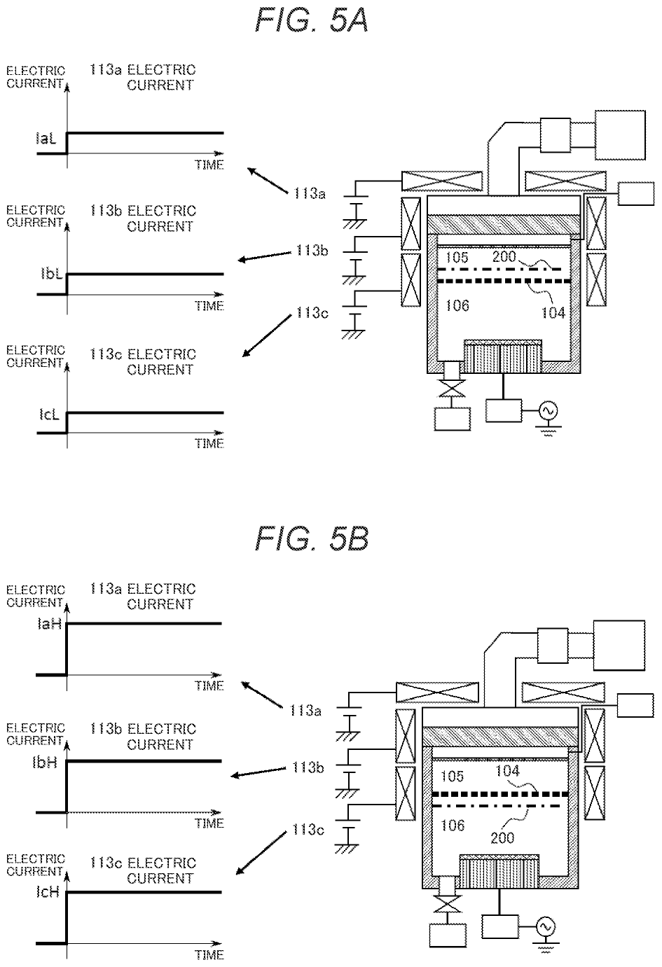

FIGS. 5A and 5B illustrate examples in which the position 200 of the ECR region corresponding to the center frequency is set by the DC coil current power supplies 113. The position of the ECR region may be regarded as the center of the ECR region. The magnetic field generated by the magnetic field generating coils 112 is weakened toward the RIE region 106 from the radical region 105, and the magnetic field stronger than that of the ECR region is generated in the upper section of the vacuum vessel 101. Accordingly, as the current becomes higher, the ECR region moves downward in the vacuum vessel 101. As FIG. 5A illustrates, in the case of low current (IaL, IbL, IcL) of each of the DC coil current power supplies 113a, 113b, and 113c, the position 200 of the resultant ECR region is located in the radical region 105 above the ion shielding plate 104. Meanwhile, as FIG. 5B illustrates, in the case of high current (IaH>IaL, IbH>IbL, IcH>IcL) of each of the DC coil current power supplies 113a, 113b, and 113c, the position 200 of the resultant ECR region is located in the RIE region 106 below the ion shielding plate 104.

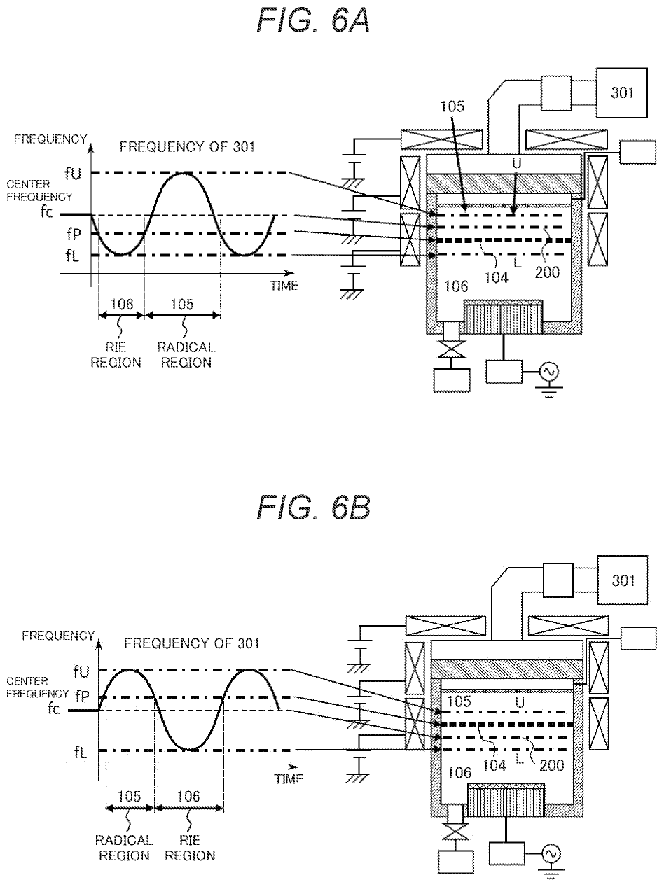

FIGS. 6A and 6B illustrate examples each indicating that the position of the ECR region has been vertically moved by the frequency of the variable frequency electromagnetic wave generating power supply 301 from the position 200 of the ECR region at the center frequency set by the magnetic field generating coils 112. FIG. 6A illustrates the upper limit U and the lower limit L of the position 200 of the ECR region, the position of the ion shielding plate 104, and frequency values (fU, fL, fP) corresponding to those positions, respectively. If the frequency is lower than a center frequency fc, the magnetic field strength required for resonance is weakened. If the frequency is lowered, the ECR region is moved downward in the vacuum vessel 101. If the frequency is higher than the center frequency, the ECR region is moved upward. As FIG. 6A illustrates, if the position 200 of the ECR region corresponding to the center frequency fc is set in the radical region 105 by the DC coil current power supplies 113, the time period for which the ECR region is positioned in the radical region 105 becomes longer than the time period for which the ECR region is positioned in the RIE region 106. As FIG. 6B illustrates, if the position of the ECR region corresponding to the center frequency fc is set in the RIE region 106 by the DC coil current power supplies 113, the time period for which the ECR region is positioned in the RIE region 106 becomes longer than the time period for which the ECR region is positioned in the radical region 105. Periodical change in the frequency of the variable frequency electromagnetic wave generating power supply 301 makes the ECR region movable between the radical region 105 and the RIE region 106 periodically without changing the magnetic field strength. In other words, the control unit 130 controls the variable frequency electromagnetic wave generating power supply (the radio frequency power supply) 301 so as to periodically change the position (200) of the region of the electron cyclotron resonance (ECR) generated by the interaction between the microwave and the magnetic field. As a result, the position 200 of the region of the electron cyclotron resonance (ECR) moves from the position above the shielding plate 104 to the position below the shielding plate 104, or from the position below the shielding plate 104 to the position above the shielding plate 104.

An explanation will be made with respect to a plasma processing method using the plasma processing device 11.

Step 1 A process step is executed for mounting the semiconductor substrate 116 as the sample on the mount stand 115 in the processing chamber 100 so that the GAA structure is formed on the surface of the semiconductor substrate.

Step 2 A process step is executed for controlling a pressure in the processing chamber 100 by operating the pressure control valve 117 and the vacuum exhaust device 118.

Step 3 A process step is executed for supplying etching gas such as oxygen and chlorine to the area between the shower plate 102 and the dielectric window 103 of the processing chamber 100 from the gas supply device 107 so as to apply the plasma etching process.

Step 4 A process step is executed for generating plasma in the processing chamber 100 by operating the variable frequency electromagnetic wave generating power supply 301 and the DC coil current power supply 113 so that the surface of the semiconductor substrate 116 is plasma processed through plasma etching. In step 4, as FIGS. 5A, 5B, 6A and 6B illustrate, the position of the ECR region is vertically moved periodically with respect to the ion shielding plate 104 so that the density ratio between ion and radical is controlled. This makes it possible to provide the technique which attains the highly accurate anisotropic etching operation.

Example 2 provides the technique which allows direct control of the density ratio between ion and radical in the anisotropic etching process through supply of ions and radicals.

### Modified Example

A plasma processing device according to a modified example will be described.
1) The modified example allows the plasma processing device 11 according to Example 2 to replace the DC coil current power supply 113c by the AC coil current power supply 114 as described in Example 1. In this case, it is necessary to set the frequency of the variable frequency electromagnetic wave generating power supply 301 and the frequency of the AC coil current power supply 114 so that the density ratio between ion and radical becomes a required value in the anisotropic etching process.
2) The plasma processing device 11 according to Example 2 may be provided with the variable frequency electromagnetic wave generating power supply 301 and the electromagnetic wave generating power supply 110 according to Example 1. The isotropic etching is performed by operating the electromagnetic wave generating power supply 110 in the state as illustrated in FIG. 5A. The anisotropic etching is performed by operating the electromagnetic wave generating power supply 110 in the state as illustrated in FIG. 5B. The anisotropic etching is performed while controlling the density ratio between ion and radical with high accuracy by operating the variable frequency electromagnetic wave generating power supply 301 as illustrated in FIGS. 6A and 6B. This allows the single unit of plasma processing device to perform the anisotropic etching process through supply of ions and radicals, and the isotropic etching process through supply of only radicals.

The plasma processing devices (10, 11) according to the first and Example 2s can be summarized as described below.
1) A plasma processing device includes a processing chamber (100) in which a sample is plasma processed, a radio frequency power supply (110, 301) which supplies microwave radio frequency power for plasma generation, a coil (112) which generates a magnetic field, a power supply (113, 114) which carries current to the coil, a sample stand (116) on which the sample is placed, a shielding plate (104) disposed above the sample stand for shielding incidence of an ion onto the sample stand, and a control unit (130) which controls the power supply to periodically change a position (200) of an electron cyclotron resonance region generated under interaction between the microwave and the magnetic field. The position of the electron cyclotron resonance region is movable from a position above the shielding plate to a position below the shielding plate, or from the position below the shielding plate to the position above the shielding plate (FIGS. 3A, 3B; 6A, 6B) in one cycle.
2) A plasma processing device includes a processing chamber (100) in which a sample is plasma processed, a radio frequency power supply (301) which supplies microwave radio frequency power for plasma generation, a coil (112) which generates a magnetic field, a power supply (113) which carries current to the coil, a sample stand (116) on which the sample is placed, a shielding plate (104) disposed above the sample stand for shielding incidence of an ion onto the sample stand, and a control unit (130) which controls the radio frequency power supply to periodically change a position (200) of an electron cyclotron resonance region generated under interaction between the microwave and the magnetic field. The position of the electron cyclotron resonance region is movable from a position above the shielding plate to a position below the shielding plate, or from the position below the shielding plate to the position above the shielding plate (FIGS. 6A, 6B) in one cycle.
3) In the plasma processing device according to 1), the power supply includes a DC power supply (113) and an AC power supply (114).
4) In the plasma processing device according to 3), the coil (112) includes a first coil (112a, 112b) connected to the DC power supply (113) and a second coil (112c) connected to the AC power supply (114), and is disposed outside the processing chamber (100). The first coil (112a, 112b) is positioned higher than the shielding plate (104). The second coil (112c) is disposed closer to the shielding plate (104) than the first coil (112a, 112b).
5) In the plasma processing device according to 4), the radio frequency power supply (301) has a variable frequency.
6) In the plasma processing device according to 2), the control unit (130) controls a frequency of the radio frequency power supply (301) so that the position (200) of the electron cyclotron resonance region is periodically changed.
7) In the plasma processing device according to 6), the power supply (113) is a DC power supply.
8) In the plasma processing device according to 3), the coil (112) includes a first coil (112a, 112b) connected to the DC power supply (113) and a second coil (112c) connected to the AC power supply (114), and is disposed outside the processing chamber (100). The control unit (130) controls the AC power supply (114) to periodically change the position (200) of the electron cyclotron resonance region generated under the interaction between the magnetic field generated by the first coil (112a, 112b) and the microwave.

The plasma processing method according to Example 1 and Example 2 can be summarized as described below.
9) A plasma processing method using a plasma processing device (10, 11) includes a processing chamber (100) in which a sample is plasma processed, a radio frequency power supply (110, 301) which supplies microwave radio frequency power for plasma generation, a coil (112) which generates a magnetic field, a power supply (113, 114) which carries current to the coil, a sample stand (116) on which the sample is placed, and a shielding plate (104) disposed above the sample stand for shielding incidence of an ion onto the sample stand. The method includes the steps of periodically changing a position (200) of an electron cyclotron resonance region generated under interaction between the microwave and the magnetic field. The position (200) of the electron cyclotron resonance region is moved from a position above the shielding plate (104) to a position below the shielding plate, or from the position below the shielding plate to the position above the shielding plate (FIGS. 3A, 3B; 6A, 6B).
10) In the plasma processing method according to 9), the position (200) of the electron cyclotron resonance region is periodically changed by controlling the current carried to the coil (112).
11) In the plasma processing method according to 9), a frequency of the radio frequency power supply (301) is controlled to periodically change the position (200) of the electron cyclotron resonance region.

The present invention made by the inventor has been exemplified in detail. It is to be readily understood that the present invention is not limited to the embodiment and example, but includes various modifications.

### LIST OF REFERENCE SIGNS

10, 11 . . . plasma processing device
100 . . . processing chamber
101 . . . vacuum vessel
102 . . . shower plate
103 . . . dielectric window
104 . . . ion shielding plate
105 . . . radical region
106 . . . RIE region
107 . . . gas supply device
108 . . . waveguide
109 . . . cavity resonator
110 . . . electromagnetic wave generating power supply
111 . . . electromagnetic wave matching unit
112 . . . magnetic field generating coil
113 . . . DC coil current power supply
114 . . . AC coil current power supply
115 . . . electrode substrate
116 . . . semiconductor processing substrate
117 . . . pressure control valve
118 . . . vacuum exhaust device
119 . . . radio frequency matching unit
120 . . . radio frequency power supply
200 . . . position of ECR region
301 . . . variable frequency electromagnetic wave generating power supply

1. A plasma processing device comprising:
a processing chamber in which a sample is plasma processed;
a radio frequency power supply which supplies microwave radio frequency power for plasma generation;
a coil which generates a magnetic field;
a power supply which carries current to the coil;
a sample stand on which the sample is placed;
a shielding plate disposed above the sample stand for shielding incidence of an ion onto the sample stand; and
a control unit which controls the power supply to periodically change a position of an electron cyclotron resonance region generated under interaction between the microwave and the magnetic field,
wherein the position of the electron cyclotron resonance region is moved from a position above the shielding plate to a position below the shielding plate, or from the position below the shielding plate to the position above the shielding plate in one cycle.

2. A plasma processing device comprising:
a processing chamber in which a sample is plasma processed;
a radio frequency power supply which supplies microwave radio frequency power for plasma generation;
a coil which generates a magnetic field;
a power supply which carries current to the coil;
a sample stand on which the sample is placed;
a shielding plate disposed above the sample stand for shielding incidence of an ion onto the sample stand; and
a control unit which controls the radio frequency power supply to periodically change a position of an electron cyclotron resonance region generated under interaction between the microwave and the magnetic field,
wherein the position of the electron cyclotron resonance region is movable from a position above the shielding plate to a position below the shielding plate, or from the position below the shielding plate to the position above the shielding plate in one cycle.

3. The plasma processing device according to claim 1,
wherein the power supply includes a DC power supply and an AC power supply.

4. The plasma processing device according to claim 3,
wherein the coil includes a first coil connected to the DC power supply and a second coil connected to the AC power supply, and is disposed outside the processing chamber;
the first coil is positioned higher than the shielding plate; and
the second coil is disposed closer to the shielding plate than the first coil.

5. The plasma processing device according to claim 4,
wherein the radio frequency power supply has a variable frequency.

6. The plasma processing device according to claim 2,
wherein the control unit controls a frequency of the radio frequency power supply so that the position of the electron cyclotron resonance region is periodically changed.

7. The plasma processing device according to claim 6,
wherein the power supply is a DC power supply.

8. The plasma processing device according to claim 3,
wherein the coil includes a first coil connected to the DC power supply and a second coil connected to the AC power supply, and is disposed outside the processing chamber; and
the control unit controls the AC power supply to periodically change the position of the electron cyclotron resonance region generated under the interaction between the magnetic field generated by the first coil and the microwave.

9. A plasma processing method using a plasma processing device which includes a processing chamber in which a sample is plasma processed, a radio frequency power supply which supplies microwave radio frequency power for plasma generation, a coil which generates a magnetic field, a power supply which carries current to the coil, a sample stand on which the sample is placed, and a shielding plate disposed above the sample stand for shielding incidence of an ion onto the sample stand, the method comprising a step of periodically changing a position of an electron cyclotron resonance region generated under interaction between the microwave and the magnetic field,
wherein the position of the electron cyclotron resonance region is moved from a position above the shielding plate to a position below the shielding plate, or from the position below the shielding plate to the position above the shielding plate in one cycle.

10. The plasma processing method according to claim 9,
wherein the position of the electron cyclotron resonance region is periodically changed by controlling the current carried to the coil.

11. The plasma processing method according to claim 9,
wherein a frequency of the radio frequency power supply is controlled to periodically change the position of the electron cyclotron resonance region.
